(19) United States
(12) Patent Application Publication
(10) Pub. No.: US 2024/0146181 A1
(43) Pub. Date: May 2, 2024

(54) METHOD FOR DRIVING TOPOLOGICAL SWITCHES OF A HALF-BRIDGE IN A POWER MODULE OF AN INVERTER

(71) Applicant: ZF Friedrichshafen AG, Friedrichshafen (DE)

(72) Inventors: Marc Rasch, Immenstaad (DE); Sebastian Besold, Neudrossenfeld (DE)

(73) Assignee: ZF Friedrichshafen AG, Friedrichshafen (DE)

(21) Appl. No.: 18/500,790

(22) Filed: Nov. 2, 2023

(30) Foreign Application Priority Data
Nov. 2, 2022 (DE) 102022211580.5

(51) Int. Cl. H02M 1/32; H02M 7/5387

(52) U.S. Cl. CPC H02M 1/32; H02M 7/5387

(57) ABSTRACT

A method for driving two mutually complementary topological switches of a half-bridge in a power module of an inverter includes detecting a bridge short circuit at one of the topological switches, de-energizing the topological switch complementary to the topological switch at which the bridge short circuit was detected, and, temporally switching off the short-circuit current in the topological switch at which the bridge short circuit was detected.

### CROSS-REFERENCE TO RELATED APPLICATION

This application claims priority to German Application No. DE 10 2022 211 580.5, filed on Nov. 2, 2022, the entirety of which is hereby fully incorporated by reference herein.

### FIELD

The present disclosure relates to the field of electromobility, in particular to the electronic modules for an electric drive.

### BACKGROUND AND SUMMARY

The use of electronic modules, such as power electronics modules, in motor vehicles has increased significantly in recent decades. This is due on the one hand to the need to improve fuel economy and vehicle performance, and on the other hand to advances in semiconductor technology. The main component of such an electronic module is a DC/AC inverter, which is used to power electrical machines such as electric motors or generators with a polyphase alternating current (AC). A direct current generated from a DC energy source, such as a battery or accumulator, is converted into a polyphase alternating current. For this purpose, the inverters include a variety of electronic components via which bridge circuits (such as half-bridges) are implemented, for example semiconductor power switches, also known as power semiconductors.

In addition to normal operation, under certain circumstances various fault conditions may also arise, which are thus outside the scope of normal operation. Nevertheless, these areas must be controlled to the extent that total failure or total destruction does not occur. One of these possible fault conditions is the bridge short circuit. During the occurrence of a bridge short circuit, a very high short-circuit current is generated, which must be detected in a timely manner and switched off as quickly as possible. The challenge here is that if the bridge short circuit is not detected in a timely manner at a topological switch, the energy value increases very rapidly, which can result in the thermal destruction of the topological switch. In addition, after the bridge short circuit is detected in a topological switch, the bridge short-circuit current should be switched off as soon as possible in order to protect the topological switch from overheating due to the rising energy value. However, during rapid shutdown, a very high overvoltage is generated at the topological switch. This voltage may exceed the maximum voltage compatibility of the semiconductor, which may also result in the destruction of the semiconductor. Therefore, it is very difficult and often involves compromises to develop a safe short-circuit withstand strength for a power electronics system and to guarantee it for all circumstances.

Thus, an object of the present disclosure is to provide a method for driving topological switches of a half-bridge in a power module of an inverter, which provides improved short-circuit withstand strength.

This object is achieved by the features of the present disclosure. Advantageous embodiments are also the subject of the present disclosure.

A method is proposed for driving two mutually complementary topological switches of a half-bridge in a power module of an inverter, wherein in a first step, a bridge short circuit is detected at one of the topological switches, and in a second step, first, the topological switch complementary to the topological switch at which the bridge short-circuit was detected is de-energized, and in a third, temporally subsequent step, the short-circuit current in the topological switch at which the bridge short circuit was detected is switched off.

By switching off the complementary topological switch just before switching off the short-circuit current in the topological switch at which the short circuit was detected, the overvoltage to the two topological switches is distributed. Thus, both the maximum overvoltage at the moment of switching off and the maximum energy to be dissipated during the short circuit are reduced.

In one embodiment, the detection of a bridge short circuit takes place in the first step by detecting a desaturation of a power semiconductor of the topological switch at which the bridge short circuit was detected.

In one embodiment, the complementary topological switch is de-energized immediately upon detection of the bridge short circuit.

In one embodiment, the method is implemented in an integrated component of the power module.

In one embodiment, one of the topological switches is a high-side switch and the other is a low-side switch, each comprising at least one power semiconductor.

Furthermore, a circuit arrangement is provided that is part of a power module of an inverter of an electronic module for driving the electric drive of a vehicle equipped with an electric drive, said circuit arrangement comprising at least one half-bridge having two mutually complementary topological switches that are driven by the described method.

Furthermore, an integrated component is provided in which the described method is implemented as a software product, wherein the integrated component is part of a power module of an inverter of an electronic module for driving the electric drive of a vehicle equipped with an electric drive.

Furthermore, an inverter comprising an integrated component is provided. Furthermore, an electric drive of a vehicle is provided, comprising an electronic module for driving the electric drive, said module comprising an inverter having a described circuit arrangement or a described integrated component or a described inverter. Further provided is a vehicle comprising a described electric drive.

Further features and advantages will be apparent from the following description of exemplary embodiments, with reference to the figures showing details according to the present disclosure, and from the claims. The individual features may be implemented individually or together in any combination in a variant of the present disclosure.

Preferred embodiments are explained in greater detail below with reference to the accompanying drawing.

### BRIEF DESCRIPTION OF THE DRAWINGS

FIG. 1 shows simulation results of a non-optimized process according to the prior art, and an optimized process according to one embodiment of the present disclosure in comparison.

FIG. 2 shows, schematically, a flow diagram of the method according to one embodiment of the present disclosure.

### DETAILED DESCRIPTION

In the following figure descriptions, the same elements or functions are given the same reference signs.

As already mentioned at the beginning, one objective of the design of circuits for power semiconductors of an inverter in the automotive sector is to provide a short-circuit withstand strength that is as high and reliable as possible.

Power modules are used in power electronics as a central switching element in electronic devices. The topological switches are realized with power semiconductors made for example of silicon Si, silicon carbide SiC, or gallium nitride GaN. For example, bipolar transistors such as IGBTs and unipolar field-effect transistors such as MOSFETs are installed. As mentioned above, a possible fault condition is a bridge short circuit in one of the half-bridges of the power electronics. Normally, one half-bridge is provided per phase. Since three phases are usually provided, three half-bridges are also usually provided, which are then referred to as a B6 bridge. Each half-bridge has two topological switches that are connected in series and are mutually complementary, which are referred to as a high-side switch and a low-side switch, respectively. Each of the topological switches is formed from at least one power semiconductor. A center tap for the electrical load, such as an electric motor, is provided between the topological switches (not shown in the figures). The topological switches are needed to convert a direct current coming from a direct current source into an alternating current that is usable for example for a motor.

In the following, the present disclosure is described on the basis of a single half-bridge, since the method can be applied analogously to a larger number of half-bridges.

When the fault condition of a bridge short circuit occurs, both series-connected power semiconductors of the topological switches are conducting and thus short-circuit the DC source (vehicle accumulator). This condition must be controlled in any power electronics topology in which such a condition can occur.

As mentioned above, a very high short-circuit current is generated during the occurrence of a bridge short circuit. This short-circuit current can be up to ten times the usual maximum load current and must be detected in a timely manner and switched off as quickly as possible. The challenge here is that if the bridge short-circuit is not detected in a timely manner at a topological switch, the energy value (consisting of the applied voltage times the current flowing through) increases very quickly, which may result in thermal destruction of the topological switch. In addition, after the bridge short circuit is detected in a topological switch, the bridge short-circuit current should be switched off as soon as possible in order to protect the topological switch from overheating due to the rising energy value. However, during rapid shutdown, a very high overvoltage is generated at the topological switch. This voltage may exceed the maximum voltage compatibility of the semiconductor, which may also result in the destruction of the semiconductor. Therefore, it is very difficult and often involves compromises to develop a safe short-circuit withstand strength for a power electronics system and to guarantee it (as far as possible) for all circumstances.

In order to provide improved short-circuit withstand strength, it is proposed that after a bridge short circuit is detected in a topological switch (hereinafter referred to as a short-circuited topological switch), the following sequence is carried out in a first step S1.

In a second step S2, before the short-circuit current in the short-circuited topological switch is switched off, the complementary topological switch, i.e. the one opposite in series, is de-energized. This takes place directly, i.e. immediately, after the short circuit has been detected, i.e. at the moment of detection and if possible without delay. Thus, the complementary topological switch (not affected by the short circuit) can also absorb part of the total overvoltage occurring due to the short circuit, thus reducing the voltage at the short-circuited topological switch. Optimally, the overvoltage is divided exactly equally between the two topological switches, wherein it is essentially sufficient if the complementary topological switch accommodates enough voltage that the energy to be accommodated by the short-circuited topological switch is significantly reduced, and thus no more damage is caused due to the overvoltage.

After the complementary topological switch has been de-energized in the second step S2, the short-circuited topological switch is opened (de-energized) in a third step S3, i.e. the short-circuit current present there is switched off. The procedure is shown in abstract form in FIG. 2.

By means of this driving procedure, the advantage arises that the (over)voltage applied across the topological switch previously affected by the short-circuit current alone is now divided between the two topological switches. Thus, the energy that the short-circuited topological switch must withstand is also significantly reduced. In addition, due to the then-lower voltage drop across both topological switches, the characteristic overvoltage pulse will have the same delta, but will start from a much lower offset and thus will not compromise the maximum dielectric strength of the topological switch.

Topological switches of half-bridges according to the present disclosure may be any type of common bipolar and/or unipolar transistors, for example IGBT, MOSFET, BJT, HEMT, JFET, thyristor. The material of the transistors may be silicon Si, silicon carbide SiC, or gallium nitride GaN. Neither of these is essential for the driving method, since said method can be applied to all types and materials.

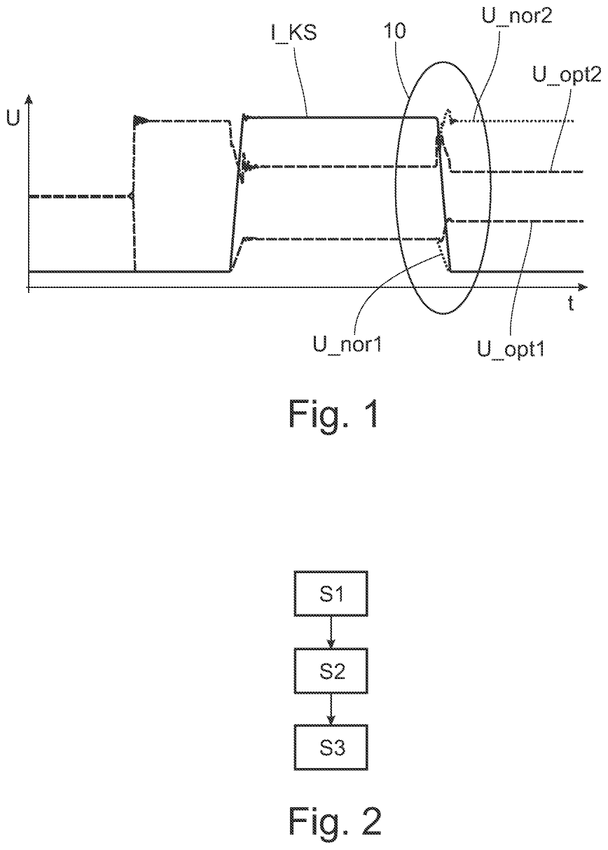

To verify the proposed method, a simulation model was used in which a typical bridge short circuit was simulated using a current standard method and a method optimized according to the present disclosure. The simulated values are superimposed in a plot in FIG. 1, wherein the units voltage U (Y-axis) and time t (X-axis) are not important here.

The characteristic curves U_nor1 and U_nor2 (each drawn in dotted lines) represent an actual shutdown procedure in which, in the event that an occurring short-circuit current I_KS is detected by for example a detection of desaturation at a topological switch (step S1), the affected topological switch (here the one with the dotted line U_nor1) is switched off as quickly as possible, i.e. immediately after detection of the short circuit. The voltage curve of the complementary topological switch is depicted by the dotted line U_nor2. The effect specifically on the cut-off overvoltage, which is depicted in the transparent oval 10 in FIG. 1, can be well illustrated in the non-optimized method (dotted line U_nor1). Here, a typical overshoot of the voltage U_nor1 of the disconnecting topological can be seen.

FIG. 1 also depicts the voltage curves of the two topological switches according to the method of the present disclosure superimposed on those of the standard method described above. Here, an earlier switch-off, i.e. currentless switching, of the complementary topological switch is performed before the actual switch-off of the standard short-circuit detection (i.e. switch-off of the short-circuited topological switch). The curves of the characteristics U_opt1, U_opt2 show the intended division of the voltage levels of the two topological switches connected in series. The curve shows that, as mentioned above, the overvoltage is split between the two topological switches. This means that the risk of overvoltage at the short-circuited topological switch is reduced, and the applied short-circuit energy is also significantly minimized, i.e. the energy input to the short-circuited topological switch is significantly reduced.

According to the present disclosure, at the instant that a short circuit is detected on one of the topological switches, the complementary topological switch is opened, whereby the voltage applied to it is raised and is thus divided between the two topological switches. As a result, the energy that the topological switch affected by the short circuit must withstand is also divided, so that it is thus relieved. In addition, due to the now-lower voltage drop across the two topological switches, the characteristic overvoltage pulse will have the same delta, but will start from a significantly lower offset and thus will not compromise the maximum dielectric strength of the topological switches.

The voltage across the topological switches will physically adjust according to the state of the output capacitances connected in series and depends on the application, for example the types and materials of semiconductors used, etc.

As a practical application, an integration of this shutdown procedure may take place in an integrated component. In addition, the currently standard detection of desaturation may be used to detect a short circuit.

By means of the proposed driving method of the circuit arrangement having at least one half-bridge used in an inverter, a highly efficient inverter, which is used for example as a drive converter or traction converter, may be achieved, in which an improved short-circuit withstand strength is realized. The circuit arrangement for which the method for driving is proposed may be used in an inverter of an electronic module for driving the electric drive of a vehicle equipped with an electric drive. Electrified axles may also be driven by the electric drive.

An electronic module within the scope of the present disclosure is used to operate an electric drive of a vehicle, in particular an electric vehicle and/or a hybrid vehicle, and/or electrified axles. The electronic module comprises a DC/AC inverter. Said module may further comprise or be a part of an AC/DC rectifier, DC/DC converter, transformer, and/or other electrical converter, or part of such a converter. In particular, the electronic module is used to power an electric machine, for example an electric motor and/or a generator. A DC/AC inverter is preferably used to generate a multi-phase AC current from a DC current generated by means of a DC voltage from an energy source, such as a battery.

### LIST OF REFERENCE SIGNS

10 Oval
U_nor1, U_nor2 Voltage curve—standard method
U_opt1, U_opt2 Voltage curve—new method
I_KS Short-circuit current
U Voltage
t Time
S1-S3 Method steps

1. A method for driving two mutually complementary topological switches of a half-bridge in a power module of an inverter, the method comprising:
detecting a bridge short circuit at one of the topological switches;
de-energizing a topological switch complementary to the topological switch at which the bridge short circuit was detected; and
temporally switching off the short-circuit current in the topological switch at which the bridge short circuit was detected subsequent to de-energizing the topological switch complementary to the topological switch at which the bridge short circuit is detected.

2. The method according to claim 1,
wherein detecting the bridge short circuit comprising detecting a desaturation of a power semiconductor of the topological switch at which the bridge short circuit was detected.

3. The method according to claim 1, comprising:
de-energizing the complementary topological switch immediately upon detection of the bridge short circuit.

4. The method according to claim 1, wherein the method is implemented in an integrated component of the power module.

5. The method according to claim 1, wherein one of the topological switches is a high-side switch and the other is a low-side switch, each comprising at least one power semiconductor.

6. A circuit arrangement that is part of a power module of an inverter of an electronic module for driving an electric drive of a vehicle, the circuit arrangement comprising:
at least one half-bridge having two mutually complementary topological switches; and
an integrated component configured to:
detect a bridge short circuit at one of the topological switches;
de-energize a topological switch complementary to the topological switch at which the bridge short circuit was detected; and
temporally switch off the short-circuit current in the topological switch at which the bridge short circuit was detected subsequent to de-energizing the topological switch complementary to the topological switch at which the bridge short circuit is detected.

7. The circuit arrangement according to claim 6,
wherein the integrated component is configured to:
detect the bridge short circuit by detecting a desaturation of a power semiconductor of the topological switch at which the bridge short circuit was detected.

8. The circuit arrangement according to claim 6,
wherein the integrated component is configured to:
de-energize the complementary topological switch immediately upon detection of the bridge short circuit.

9. The circuit arrangement according to claim 6,
wherein one of the topological switches is a high-side switch and the other is a low-side switch, each comprising at least one power semiconductor.

10. An integrated component that is part of a power module of an inverter of an electronic module for driving an electric drive of a vehicle equipped, wherein the integrated component is configured to:
detect a bridge short circuit at one of the topological switches;
de-energize a topological switch complementary to the topological switch at which the bridge short circuit was detected; and
temporally switch off the short-circuit current in the topological switch at which the bridge short circuit was detected subsequent to de-energizing the topological switch complementary to the topological switch at which the bridge short circuit is detected.

11. The integrated component according to claim 10,
wherein the integrated component is configured to:
detect the bridge short circuit by detecting a desaturation of a power semiconductor of the topological switch at which the bridge short circuit was detected.

12. The integrated component according to claim 10,
wherein the integrated component is configured to:
de-energize the complementary topological switch immediately upon detection of the bridge short circuit.

13. The integrated component according to claim 10,
wherein one of the topological switches is a high-side switch and the other is a low-side switch, each comprising at least one power semiconductor.

14. An inverter comprising:
the integrated component according to claim 10.

15. An electric drive of a vehicle, comprising:
an electronic module for driving the electric drive, the electronic module comprising the inverter according to claim 14.

16. A vehicle comprising:
the electric drive according to claim 15.
